(19) United States
(12) Patent Application Publication
(10) Pub. No.: US 2025/0250713 A1
(43) Pub. Date: Aug. 7, 2025

(54) LOW-TRANSMISSION-LOSS SINGLE-CRYSTAL COPPER MATERIAL AND PREPARATION METHOD THEREFOR, PCB AND PREPARATION METHOD THEREFOR AND ELECTRONIC COMPONENT

(71) Applicants: SONGSHAN LAKE MATERIALS LABORATORY, Guangdong (CN); ZHONGKE CRYSTAL MATERIALS (DONGGUAN) CO., LIMITED, Guangdong (CN)

(72) Inventors: Zhiqiang Ding, Dongguan. Guangdong (CN); Zhiqiang Zhang, Dongguan, Guangdong (CN); Menglin He, Dongguan, Guangdong (CN); Zhi Huang, Dongguan, Guangdong (CN); Xiangbin Yue, Dongguan, Guangdong (CN); Enge Wang, Dongguan, Guangdong (CN)

(21) Appl. No.: 18/563,302

(22) PCT Filed: Nov. 23, 2022
(86) PCT No.: PCT/CN2022/133743

§ 371 Date: Nov. 21, 2023

(30) Foreign Application Priority Data
Oct. 27, 2022 (CN) 202211323127.8

(51) Int. Cl. C30B 23/02; C25D 1/20; C25D 3/38; C25D 5/50; C25D 5/54; C30B 1/02; C30B 29/02; H05K 1/09; H05K 3/00

(52) U.S. Cl. CPC C30B 23/025; C25D 1/20; C25D 3/38; C25D 5/50; C25D 5/54; C30B 1/02; C30B 29/02; H05K 1/09; H05K 3/00

(57) ABSTRACT

The present disclosure relates to the technical field of copper material preparation, in particular, to a low-transmission-loss single-crystal copper material and a preparation method thereof, a PCB and a preparation method thereof and an electronic component. The preparation method of the low-transmission-loss single-crystal copper material includes: forming a single-crystal copper layer on a substrate with a graphene layer on the surface in a mixed gas atmosphere of argon and hydrogen and at a temperature of 800-1065° C., then peeling off the single-crystal copper layer from the substrate. The volume ratio of argon and hydrogen in the mixed gas is (10-20):1. The preparation method of the low-transmission-loss single-crystal copper material provided by the present disclosure can significantly reduce the surface roughness Rz of the formed copper material, which is beneficial to further reducing the transmission loss of the entire low-transmission-loss single-crystal copper material, and the preparation method is simple and easy to operate.

### CROSS-REFERENCE TO RELATED APPLICATIONS

The present disclosure claims the priority to Chinese Patent Application No. 202211323127.8 filed on Oct. 27, 2022 with the Chinese Patent Office, entitled “Low-Transmission-Loss Single-Crystal Copper Material and Preparation Method Therefor, PCB and Preparation Method Therefor and Electronic Component”, the entire content of which is incorporated in the present disclosure by reference.

### TECHNICAL FIELD

The present disclosure relates to the technical field of copper material preparation, in particular to a low-transmission-loss single-crystal (monocrystalline) copper material and a preparation method therefor, a PCB and a preparation method therefor, and an electronic component.

### BACKGROUND ART

The signal layer of the printed circuit board (PCB) works as a “bridge” for the interconnection of various electronic components. The conductivity and roughness of the conductor material used in the signal layer determine the integrity and stability of signal transmission. With the rapid development of information technology, higher requirements are put forward for the transmission quality and transmission speed of signals. In the context of 5G, 6G and other communication technologies, ensuring the integrity of high-frequency and high-speed signals is facing great challenges.

The transmission loss of the signal layer mainly depends on the conductivity and surface roughness of the conductor material. The increase of signal frequency will lead to obvious skin effect, resulting in different degrees of signal attenuation.

Due to the advantages such as excellent electrical conductivity, wide source and low price, copper material has become a conductor material commonly used in the signal layer. However, the surface roughness of the copper material in the related art is relatively high, such that the signal transmission loss cannot be effectively reduced, which greatly limits the application of the copper material in high-frequency and high-speed signal transmission.

### SUMMARY

The present disclosure provides a low-transmission-loss single-crystal copper material and preparation method therefor, PCB and preparation method therefor and an electronic component, which at least solve the technical problem that high surface roughness of the copper material in the related art causes high transmission loss of copper material.

In some embodiments of the present disclosure, the present disclosure provides a preparation method for a low-transmission-loss single-crystal copper material, the preparation method can include: forming a single-crystal copper layer on a substrate whose surface is a graphene layer, and peeling the single-crystal copper layer from the substrate, in a mixed gas atmosphere of argon and hydrogen, at a temperature of 800-1065° C., wherein the volume ratio of argon to hydrogen is (10-20):1 in the mixed gas.

Graphene has a low roughness and copper has high degree of lattice match with graphene. The copper layer obtained by forming a copper layer on a substrate whose surface is a graphene layer can replicate the low surface roughness Rz of the graphene layer. By setting the volume ratio of argon to hydrogen as (10-20):1 and the temperature as 800-1065° C., the copper layer formed can have higher single-crystal property, which can significantly reduce the surface roughness Rz of the formed copper layer, and can also enable the formed low-transmission-loss single-crystal copper material to have good etching performance, thereby making the etched section of the low-transmission-loss single-crystal copper material closer to a rectangle, increasing the effective area of signal transmission effectively, and then further conducing to reducing the transmission loss of the entire low-transmission-loss single-crystal copper material. The transmission performance of the low-transmission-loss single-crystal copper material provided by the present disclosure approaches that of VLP copper foil (very low profile copper foil) and HVLP copper foil (high-frequency very low profile copper foil) and other high-end copper foil.

In addition, since the bonding force between the formed single-crystal copper layer and the graphene layer on the substrate is weak, the single-crystal copper layer is convenient to be peeled off from the substrate, after the single-crystal copper layer is formed on the substrate, such that a single-crystal copper material with low-transmission-loss is obtained, of which the preparation method is simple and feasible.

In some embodiments of the present disclosure, the graphene layer can be a single-crystal graphene layer.

The graphene layer is a single-crystal graphene layer, which contributes to further reducing the surface roughness Rz of the entire low-transmission-loss single-crystal copper material, thereby helping to further reduce the signal transmission loss of the entire low-transmission-loss single-crystal copper material.

In some embodiments of the present disclosure, the step of preparing the single-crystal copper layer can include forming a single-crystal copper layer by atomic deposition on the graphene layer of the substrate in a mixed gas atmosphere at a temperature of 800-1065° C.

By combining with the mixed gas atmosphere and temperature condition defined in the present disclosure, and adopting atomic deposition to form a single-crystal copper layer on the graphene layer of the substrate, it is beneficial to further reducing the surface roughness Rz of the entire low-transmission-loss single-crystal copper material, thereby further reducing the signal transmission loss of the entire low-transmission-loss single-crystal copper material.

In some embodiments of the present disclosure, the temperature for preparing the single-crystal copper layer can be 900-1000° C., and the volume ratio of argon and hydrogen in the mixed gas can be (13-15):1.

Under the above conditions, it is beneficial to further reducing the surface roughness Rz of the entire low-transmission-loss single-crystal copper material, which is beneficial to further reducing the signal transmission loss of the entire low-transmission-loss single-crystal copper material.

Optionally, the substrate can be a sapphire substrate with a graphene layer on the surface.

In some embodiments of the present disclosure, the preparation step of the single-crystal copper layer can include: electroplating copper on the graphene layer of the substrate to form an electroplated copper layer, and then annealing in a mixed gas atmosphere and at a temperature of 800-1065° C., so that the electroplated copper layer is converted into a single-crystal copper layer.

The above method of forming the single-crystal copper layer can improve the preparation efficiency of the single-crystal copper layer on the basis of effectively reducing the surface roughness Rz of the entire low-transmission-loss single-crystal copper material.

In some embodiments of the present disclosure, the temperature for preparing the single-crystal copper layer can be 900-1000° C., and the volume ratio of argon to hydrogen in the mixed gas can be (13-15):1.

Under the above conditions, it is beneficial to further reducing the surface roughness Rz of the entire low-transmission-loss single-crystal copper material, which is beneficial to further reducing the signal transmission loss of the entire low-transmission-loss single-crystal copper material.

Optionally, the substrate can be a copper substrate with a graphene layer on the surface.

Optionally, the substrate can be a single-crystal copper substrate with a graphene layer on the surface.

The substrate is a single-crystal copper substrate with a graphene layer on the surface. Because the (111) crystal orientation of single-crystal copper has higher lattice matching degree of single-crystal graphene, the single-crystal property of the copper layer formed by growth can be ensured, which is beneficial to further reducing the surface roughness Rz of the entire low-transmission-loss single-crystal copper material, thereby further reducing the signal transmission loss of the entire low-transmission-loss single-crystal copper material.

In some other embodiments of the present disclosure, the present disclosure provides a low-transmission-loss single-crystal copper material, the low-transmission-loss single-crystal copper material can be prepared by preparation method of the low-transmission-loss single-crystal copper material provided by some embodiments mentioned above.

The low-transmission-loss single-crystal copper material prepared by the preparation method of the low-transmission-loss single-crystal copper material provided by the present disclosure has a lower surface roughness Rz, thereby realizing that the entire low-transmission-loss single-crystal copper material has lower transmission loss, so as to realize the good application of low-transmission-loss single-crystal copper material in high-frequency and high-speed signal transmission.

In some other embodiments of the present disclosure, the present disclosure provides a PCB, the PCB can include a signal layer and a first dielectric layer covering the surface of the signal layer, wherein the material of the signal layer includes the low-transmission-loss single-crystal copper material provided by some aforementioned embodiments.

The PCB provided by the present disclosure uses low-transmission-loss single-crystal copper material with low surface roughness Rz, thus the PCB has relatively low signal transmission loss, which is beneficial to its application in high-frequency and high-speed signal transmission.

Optionally, the signal layer can have a signal transmission line structure, wherein the signal transmission line structure has a plurality of sequentially connected S-shaped transmission units.

The above setting method contributes to further reducing the signal transmission loss of the PCB.

Optionally, the PCB can also include a base and a first composite layer and a second composite layer respectively covering two opposite sides in the thickness direction of the base, wherein both the first composite layer and the second composite layer include a first dielectric layer, a signal layer, a second dielectric layer, and a reference layer that cover the surface of the base sequentially along the thickness direction of the base.

The above setting method is beneficial to improving the stability of signal transmission and the anti-interference performance of signal transmission.

Optionally, along the extending direction of the signal transmission line structure, the distance between the two opposite endpoints of the signal transmission line structure in the first composite layer can be different from the distance between the two opposite endpoints of the signal transmission line structure in the second composite layer.

The above setting method is beneficial to avoiding signal crosstalk caused by wiring on the same layer, thereby further improving the stability and anti-interference performance of the signal transmission of the entire PCB.

Optionally, along the direction from the first dielectric layer to the second dielectric layer, the width of the signal transmission line structure gradually increases, and the difference between surface width of the signal transmission line structure close to the first dielectric layer and surface width of the signal transmission line structure close to the second dielectric layer can be less than 0.3 mil.

Since the signal layer of the present disclosure uses a low-transmission-loss single-crystal copper material with a relatively low surface roughness Rz, when the signal layer is etched to form a signal transmission line structure, the signal transmission line structure formed by etching has fewer burrs or even no burrs and has less residual copper or even no residual copper. Compared with the trapezoidal section structure of traditional copper materials formed by etching, the etched section of the low-transmission-loss single-crystal copper material provided by the present disclosure is closer to a rectangle, thereby having a larger transmission area, which is conducive to further reducing the signal transmission loss of the PCB.

Optionally, the PCB can further include a connection layer, wherein the connection layer is disposed between the first dielectric layer and the signal layer, and the material of the connection layer is a silane coupling agent.

The arrangement of the connection layer is beneficial to increasing the bonding force between the first dielectric layer and the signal layer, thereby conducing to improving the structural stability of the entire PCB.

In some embodiments of the present disclosure, the thickness of the reference layer can be 10 μm-100 μm, the thickness of the signal layer can be 3 μm-70 μm. The materials of the first dielectric layer and the second dielectric layer can be a composite material of glass fiber and resin, and the thicknesses of the first dielectric layer and the second dielectric layer can be each independently 10 μm-400 μm.

In some embodiments of the present disclosure, the distance between the two opposite endpoints of the signal transmission line structure in the first composite layer can be 7 inch-10 inch, and the distance between two opposite endpoints of the signal transmission line structure in the second composite layer can be 12 inch-15 inch.

In some embodiments of the present disclosure, along the direction from the first dielectric layer to the second dielectric layer, the width of the signal transmission line structure gradually increases, and the difference between the surface width of the signal transmission line structure close to the first dielectric layer and the surface width of the signal transmission line structure close to the second dielectric layer can be 0.1 mil-0.3 mil.

In some embodiments of the present disclosure, the surface width of the signal transmission line structure close to the first dielectric layer can be 7.2 mil-7.3 mil, and the surface width of the signal transmission line structure close to the second dielectric layer can be 74 mil-7.6 mil.

In some embodiments of the present disclosure, the silane coupling agent can include at least one of methacryloxysilane and 3-aminopropyltrimethoxysilane.

In some further embodiments of the present disclosure, the present disclosure provides an electronic component, wherein the electronic component can include the PCB provided in the other embodiments described above.

The electronic component provided by the present disclosure has low signal transmission loss, and good signal transmission stability and anti-interference performance, which has good application in high-frequency and high-speed signal transmission.

In some further embodiments of the present disclosure, the present disclosure provides a method for preparing the PCB provided in some further embodiments described above, including coating the surface of the signal layer with a silane coupling agent, and then laminating the surface of signal layer coated by silane coupling agent and the first dielectric layer.

The use of the silane coupling agent is conducive to increasing the bonding force between the first dielectric layer and the signal layer, thereby conducing to improving the structural stability of the entire PCB.

Optionally, the silane coupling agent can include at least one of methacryloxysilane and 3-aminopropyltrimethoxysilane.

Optionally, the method for preparing the PCB can further include deoxidizing and drying the surface of the signal layer sequentially, before coating the surface of the signal layer with a silane coupling agent.

The deoxidizing treatment is beneficial to further increasing the bonding force between the first dielectric layer and the signal layer.

Optionally, the deoxidizing treatment can be performed via acid, alkali or hydrogen peroxide.

### BRIEF DESCRIPTION OF DRAWINGS

In order to more clearly illustrate the technical solutions of the embodiments of the present disclosure, the following will briefly introduce the accompanying drawings used in the embodiments. It should be understood that the following drawings only show some embodiments of the present disclosure, therefore should not be regarded as a limitation on the scope, and those skilled in the art can also obtain other related drawings based on these drawings without inventive effort.

FIG. 1 shows a sectional view of a PCB provided by the present disclosure.

FIG. 2 shows a schematic structural view of the signal layer and the second dielectric layer in the PCB provided by the present disclosure.

FIG. 3 shows a schematic structural view of the signal transmission line structure in the PCB provided by the present disclosure.

FIG. 4 shows a sectional view along the direction B-B at A in FIG. 3.

FIG. 5 shows the XRD pattern of the copper material provided in Example 1 of the present disclosure.

FIG. 6 shows the XRD pattern of the copper material provided in Comparative Example 1 of the present disclosure.

FIG. 7 shows the Raman spectrogram of the copper material provided in Example 1 of the present disclosure.

FIG. 8 shows a SEM image of the copper material provided in Example 1 of the present disclosure.

FIG. 9 shows the transmission loss diagram of PCBs prepared using the copper materials provided in Example 2 and Comparative Example 7 of the present disclosure.

Reference numerals: 100—PCB; 101—extension direction; 110—base; 120—first composite layer; 130—second composite layer; 140—first dielectric layer; 150—signal layer; 151—signal transmission line structure; 1511—transmission unit; 160—second dielectric layer; 170—reference layer; 180—connection layer.

### DETAILED DESCRIPTION OF EMBODIMENTS

In order to make the purpose, technical solutions and advantages of the embodiments of the present disclosure clearer, the technical solutions in the embodiments of the present disclosure will be clearly and completely described below. Those without specific indicated conditions in the examples are carried out according to the conventional conditions or the conditions suggested by the manufacturer. The reagents or instruments used without indicated manufacturer are all conventional products that could be purchased from the market.

The present disclosure provides a preparation method for a low-transmission-loss single-crystal copper material, the preparation method can include that in a mixed gas atmosphere of argon and hydrogen and at a temperature of 800-1065° C., a single-crystal copper layer is formed on the substrate whose surface is graphene surface, and the single-crystal copper layer is peeled off from the substrate, wherein the volume ratio of argon to hydrogen in the mixed gas is (10-20):1.

Graphene can have a lower roughness and the copper has high degree of lattice match with graphene, and a copper layer is formed on a substrate whose surface is a graphene layer, such that the obtained copper layer can replicate the low surface roughness Rz of the graphene layer. The volume ratio of argon to hydrogen can be (10-20):1 accompanying with the temperature of 800-1065° C., which can make the formed copper layer have higher single-crystal property (fewer or no grain boundary), thereby significantly reducing the surface roughness Rz of the formed copper layer, and also enabling the formed low-transmission-loss single-crystal copper material to have good etching performance. As a result, the etched section of the low-transmission-loss single-crystal copper material is closer to a rectangle, so that the effective area of signal transmission is effectively increased, thereby conducing to further reducing the transmission loss of the entire low-transmission-loss single-crystal copper material. The transmission performance of the low-transmission-loss single-crystal copper material provided by the present disclosure is comparable to that of high-end copper foils such as VLP copper foil (very low profile copper foil) and HVLP copper foil (high-frequency very low profile copper foil).

In addition, since the bonding force between the formed single-crystal copper layer and the graphene layer on the substrate is weak, after the single-crystal copper layer is formed on the substrate, it is convenient to peel off the single-crystal copper layer from the substrate to obtain the low-transmission-loss single-crystal copper material. The preparation method is simple and feasible.

Exemplarily, the temperature for forming the single-crystal copper layer can be 800° C., 850° C., 900° C., 920° C., 930° C., 950° C., 970° C., 980° C., 990° C., 1065° C. and so on; the volume ratio of argon and hydrogen in the mixed gas can be 10:1, 12:1, 12.5:1, 13:1, 13.5:1, 14:1, 14.5:1, 15:1, 15.5:1, 16:1, 18:1 or 20:1 and so on.

Optionally, the graphene layer can be a single-crystal graphene layer. Since the (111) crystal orientation of single-crystal copper has a high degree of lattice match with the single-crystal graphene, the single-crystal property of the copper layer formed by growth can be guaranteed, which is beneficial to further reducing the surface roughness Rz of the entire low-transmission-loss single-crystal copper material, thereby further contributing to reducing the signal transmission loss of the entire low-transmission-loss single-crystal copper material.

In the present disclosure, the preparation steps for forming a single-crystal copper layer can adopt the following steps: in a mixed gas atmosphere with a volume ratio of argon and hydrogen of (10-20):1 and at a temperature of 800-1065° C., forming a single-crystal copper layer by atomic deposition on the graphene layer of the substrate.

Combining the mixed gas atmosphere and temperature condition defined in the present disclosure, adopting atomic deposition to form a single-crystal copper layer on the graphene layer of the substrate is beneficial to further reducing the surface roughness Rz of the entire low-transmission-loss single-crystal copper material, thereby further reducing the signal transmission loss of the entire low-transmission-loss single-crystal copper material.

Optionally, when the single-crystal copper layer is formed by atomic deposition, the temperature for preparing the single-crystal copper layer can be 900-1000° C., and the volume ratio of argon to hydrogen in the mixed gas can be (13-15):1. Under the above conditions, it is beneficial to further reducing the surface roughness Rz of the entire low-transmission-loss single-crystal copper material, thereby helping to further reduce the signal transmission loss of the entire low-transmission-loss single-crystal copper material.

Exemplarily, when the single-crystal copper layer is formed by atomic deposition, the temperature for preparing the single-crystal copper layer can be 900° C., 920° C., 94° C., 950° C., 970° C., 1000° C. and so on; the volume ratio of argon and hydrogen in the mixed gas can be 13:1, 13.5:1, 14:1, 14.5:1, 15:1 and so on.

Exemplarily, when the single-crystal copper layer is formed by atomic deposition, the substrate is a sapphire substrate with a graphene layer on the surface. The 6N high-purity copper target material is used as the copper source during atomic deposition.

Alternatively, in the present disclosure, the preparation step of forming a single-crystal copper layer can also adopt the following steps: electroplating copper on the graphene layer of the substrate to form an electroplating copper layer, and then annealing in a mixed gas atmosphere and at a temperature of 800-1065° C., so as to transform the electroplated copper layer into a single-crystal copper layer Compared with the above-mentioned method of forming a single-crystal copper layer by atomic deposition, the method of converting the electroplated copper layer into a single-crystal copper layer after annealing provided by the present disclosure can further improve the preparation efficiency of the single-crystal copper layer (that is, the time consumed for forming the single-crystal copper layer is shorter) on the basis of effectively reducing the surface roughness Rz of the entire low-transmission-loss single-crystal copper material.

However, compared with the method of converting the electroplated copper layer into a single-crystal copper layer after annealing, the method of directly forming a single-crystal copper layer by atomic deposition can further reduce the surface roughness Rz of the obtained single-crystal copper layer, and then further reduce the signal transmission loss of the entire low-transmission-loss single-crystal copper material. Therefore, in the present disclosure, taking time cost and transmission loss performance into comprehensive consideration, when the thickness of the single-crystal copper layer required to be formed is smaller than or equal to 3 μm, the atomic deposition method is selected to form the single-crystal copper layer; when the thickness of the single-crystal copper layer required to be formed is larger than 3 μm, the electroplated copper layer is annealed to form a single-crystal copper layer.

Optionally, when the single-crystal copper layer is formed by converting the electroplated copper layer into a single-crystal copper layer after annealing, the temperature for preparing the single-crystal copper layer can be 900-1000° C., and the volume ratio of argon to hydrogen in the mixed gas is (13-15): 1. Under the above conditions, it is beneficial to further reducing the surface roughness Rz of the entire low-transmission-loss single-crystal copper material, thereby contributing to further reducing the signal transmission loss of the entire low-transmission-loss single-crystal copper material.

Exemplarily, when the single-crystal copper layer is formed by converting the electroplated copper layer into a single-crystal copper layer after annealing, the temperature for preparing the single-crystal copper layer can be 900° C., 920° C., 940° C., 950° C., 970° C., 1000° C. and so on, and the volume ratio of argon and hydrogen in the mixed gas can be 13:1, 13.5:1, 14:1, 14.5:1, 15:1 and so on.

Exemplarily, when the single-crystal copper layer is formed by converting the electroplated copper layer into a single-crystal copper layer after annealing, the substrate is a copper substrate with a graphene layer on the surface, Optionally, the substrate can be a single-crystal copper substrate with a graphene layer on the surface, which is beneficial to further reducing the surface roughness Rz of the entire low-transmission-loss single-crystal copper material, thereby conducing to further reducing the signal transmission loss of the entire low-transmission-loss single-crystal copper.

The present disclosure also provides a low-transmission-loss single-crystal copper material, wherein the low-transmission-loss single-crystal copper material can be prepared by the preparation method of the low-transmission-loss single-crystal copper material as provided above.

The low-transmission-loss single-crystal copper material prepared by the preparation method of the low-transmission-loss single-crystal copper material provided by the present disclosure has a lower surface roughness Rz, which realizes that the entire low-transmission-loss single-crystal copper material has lower transmission loss, thereby realizing the good application of low-transmission-loss single-crystal copper material in high-frequency and high-speed signal transmission.

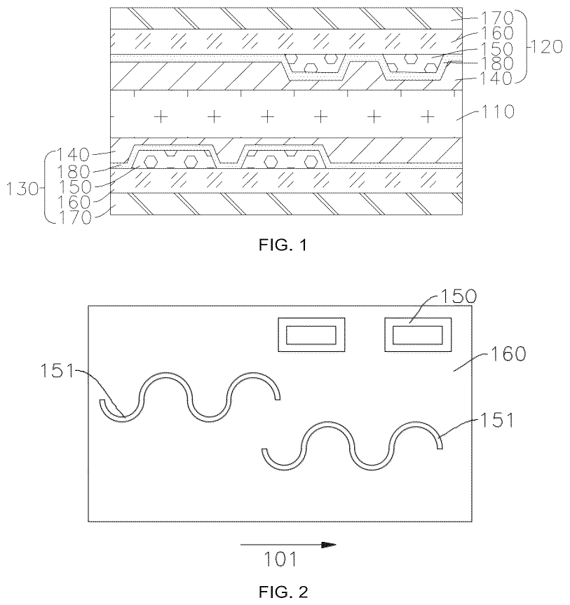

The present disclosure also provides a PCB. FIG. 1 shows a sectional view of the PCB 100 provided in the present disclosure, Referring to FIG. 1, the PCB 100 can include a signal layer 150, wherein the signal layer 150 is configured for transmitting signals. In the present disclosure, the material of the signal layer 150 can be the low-transmission-loss single-crystal copper material described above.

The PCB 100 provided by the present disclosure uses low-transmission-loss single-crystal copper material with a relatively low surface roughness Rz, so that the PCB 100 has lower signal transmission loss, which is beneficial to its application in high-frequency and high-speed signal transmission.

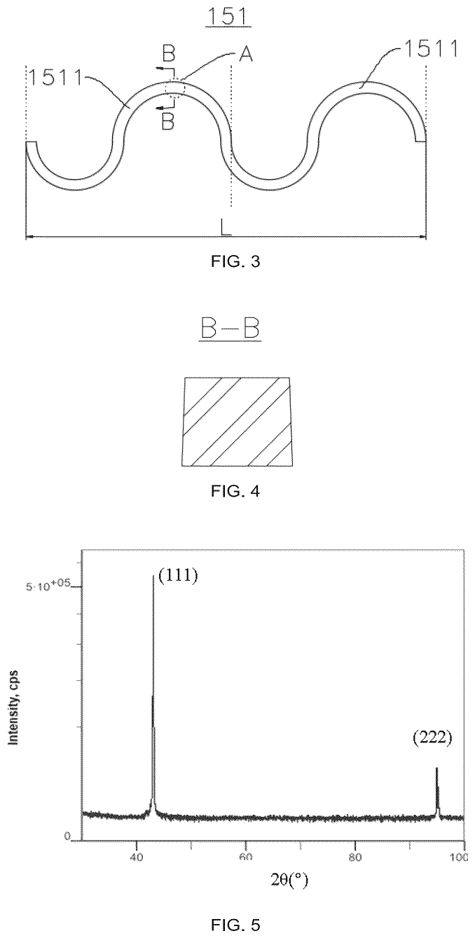

FIG. 2 shows a schematic structural view of the signal layer 150 and the second dielectric layer 160 in the PCB 100 provided by the present disclosure, and FIG. 3 shows a schematic structural view of the signal transmission line structure 151 in the PCB 100 provided by the present disclosure. Referring to FIG. 2-FIG. 3, the signal layer 150 has a signal transmission line structure 151, wherein the signal transmission line structure 151 has a plurality of connected S-shaped transmission units 1511. It should be noted that the transmission unit 1511 refers to the structure between two adjacent dotted lines in FIG. 3. Compared with the scheme in which the signal transmission line structure 151 is a continuous zigzag transmission unit, the above-mentioned arrangement is beneficial to further reducing the signal transmission loss of the PCB 100.

Referring to FIG. 1 again, the PCB 100 can also include a base 110 and a first composite layer 120 and a second composite layer 130 respectively covering the two opposite sides of the base 110 in the thickness direction, wherein the first composite layer 120 and the second composite layer 130 each include a first dielectric layer 140, a signal layer 150, a second dielectric layer 160 and a reference layer 170 sequentially covering the surface of the base 110 along the thickness direction of the base 110. The above configuration is beneficial to improving the stability of the signal transmission of the PCB 100 and the anti-interference performance of the signal transmission.

Exemplarily, the material of the reference layer 170 can be common copper foil, the thickness of the reference layer 170 can be 10-100 μm, the thickness of the signal layer 150 can be 3-70 μm, the material of first dielectric layer 140 and the second dielectric layer 160 both can be a composite material of glass fiber and resin, and the thickness of the first dielectric layer 140 and the second dielectric layer 160 can be each 10-400 μm independently.

Along the extension direction 101 of the signal transmission line structure 151, the distance between the two opposite endpoints of the signal transmission line structure 151 in the first composite layer 120 and the distance between the two opposite endpoints of the signal transmission line structure 151 in the second composite layer 130 can be different. It should be noted that, along the extension direction 101 of the signal transmission line structure 151, the distance between two opposite endpoints of the signal transmission line structure 151 refers to the distance indicated by L in FIG. 3. The above configuration method is beneficial to avoiding signal crosstalk caused by wiring on the same layer, thereby further improving the stability and anti-interference performance of the signal transmission of the entire PCB 100.

Exemplarily, the distance between the two opposite ends of the signal transmission line structure 151 in the first composite layer 120 is 7-10 inch, and the distance between the two opposite ends of the signal transmission line structure 151 in the second composite layer 130 can be 12-15 inch.

FIG. 4 shows the sectional view along the B-B direction at A in FIG. 3. Referring to FIG. 4, along the direction that the first dielectric layer 140 points to the second dielectric layer 160, the width of the signal transmission line structure 151 increases gradually, and the difference between the surface width of the signal transmission line structure 151 close to the first dielectric layer 140 and the surface width of the signal transmission line structure 151 close to the second dielectric layer 160 is less than 0.3 mil.

Exemplarily, along the direction from the first dielectric layer 140 to the second dielectric layer 160, the width of the signal transmission line structure 151 gradually increases, and the difference between the surface width of the signal transmission line structure 151 close to the first dielectric layer 140 and the surface width of the signal transmission line structure 151 close to the second dielectric layer 160 can be 0.1-0.3 mil.

Line etching is an important link in the manufacture of PCB 100. The section of the signal transmission line structure 151 after etching is generally a trapezoidal section, which is because the chemical etching process starts from the surface of the signal layer 150 and gradually moves inwardly. When the signal transmission line structure 151 is formed, over-etching occurs on the top of the signal transmission line structure 151.

The signal layer 150 of the present disclosure uses a low-transmission-loss single-crystal copper material with a relatively low surface roughness Rz, wherein the single-crystal copper has no anisotropy, so the rate of each orientation is basically the same when etching the signal transmission line structure 151, and the (111) crystal surface of the single-crystal copper has a faster reaction speed with the etchant, such that when the signal transmission line structure 151 is etched, over-etching on the top of the signal transmission line structure 151 can be effectively reduced, such that the signal transmission line structure 151 formed by etching has less burrs or even no burrs, and has less or even no residual copper, when the signal layer 150 is etched to form a signal transmission line structure 151. Compared with the trapezoidal sectional structure formed after etching traditional copper material, the section of the low-transmission-loss single-crystal copper material after etching provided by the present disclosure is closer to a rectangle (as shown in FIG. 4), thereby enabling the signal transmission line structure 151 to have a larger transmission area, which is beneficial to further reducing the signal transmission loss of the PCB 100.

Exemplarily, the difference between the surface width of the signal transmission line structure 151 close to the first dielectric layer 140 and the surface width of the signal transmission line structure 151 close to the second dielectric layer 160 can be 0.05 mil, 0.1 mil, 0.15 mil, 0.2 mil, 0.25 mil, 0.3 mil and so on.

In some embodiments of the present disclosure, the surface width of the signal transmission line structure 151 close to the first dielectric layer 140 can be 7.2-7.3 mil, and the surface width of the signal transmission line structure 151 close to the second dielectric layer 160 can be 7.4-7.6 mil.

Referring to FIG. 1 again, the PCB 100 can further include a connection layer 180, which is disposed between the first dielectric layer 140 and the signal layer 150, wherein the material of the connection layer 180 is a silane coupling agent. The arrangement of the connection layer 180 is beneficial to increasing the bonding force between the first dielectric layer 140 and the signal layer 150, thereby contributing to improving the structural stability of the entire PCB 100.

Exemplarily, the silane coupling agent can be selected from at least one of methacryloxysilane and 3-aminopropyltrimethoxysilane. The thickness of the connection layer 180 can be 200-300 nm.

The present disclosure also provides an electronic component (not shown in the figure), the electronic component can include the PCB 100 described above. The electronic component provided by the present disclosure have lower signal transmission loss, and good signal transmission stability and anti-interference performance, thereby having good application in high-frequency and high-speed signal transmission.

The present disclosure also provides a preparation method of PCB, in which the structure of the PCB refers to the above content, which will not be repeated here. The preparation method of the PCB generally includes stacking the signal layer, the second dielectric layer and the reference layer in sequence and laminating them together, then etching the signal transmission line structure on the signal layer to form a primary composite layer; after that, coating the first dielectric layer on both sides of the board in the thickness direction, and then covering the primary composite layer respectively on the side of the first dielectric layer away from the base, contacting the signal layer with the first dielectric layer, and then pressing to form a PCB.

In the present disclosure, the preparation method of the PCB can include coating the surface of the signal layer with a silane coupling agent, and then laminating the surface of the signal layer coated with the silane coupling agent with the first dielectric layer Since the material of the signal layer in the present disclosure is low-transmission-loss single-crystal copper material with relatively low surface roughness Rz, it is possible to improve the bonding force between the signal layer and the first dielectric layer.

In the present disclosure, by coating the silane coupling agent between the first dielectric layer and the signal layer, it is beneficial to increasing the bonding force between the first dielectric layer and the signal layer, thereby improving the structural stability of the entire PCB.

Exemplarily, the silane coupling agent can be at least one selecting from the group consisting of methacryloxysilane and 3-aminopropyltrimethoxysilane.

Optionally, the preparation method of the PCB can further include before coating the surface of the signal layer with the silane coupling agent, sequentially deoxidating and drying the surface of the signal layer. The deoxidating treatment and drying treatment are beneficial to further increasing the bonding force between the first dielectric layer and the signal layer.

Optionally, acid, alkali or hydrogen peroxide can be selected for deoxidating treatment. The above-mentioned substances can effectively remove the oxide film on the surface of the signal layer, which is conducive to further improving the bonding force between the first dielectric layer and the signal layer, such that the structural stability of the entire PCB is stronger.

### Example 1

This example provided a low-transmission-loss single-crystal copper material, which was prepared by the following steps:
taking the 6N high-purity copper target material as the copper source, in a mixed gas atmosphere with a volume ratio of argon to hydrogen of 14:1 and at a temperature of 950° C., forming a single-crystal copper layer on a sapphire substrate with a single-crystal graphene layer on the surface; and peeling off the single-crystal copper layer from the substrate to obtain a low-transmission-loss single-crystal copper material with a thickness of 18 μm.

### Example 2

This example provided a low-transmission-loss single-crystal copper material, which was prepared by the following steps:
electroplating on a single-crystal copper substrate whose surface was a single-crystal graphene layer to form an electroplated copper layer, then annealing, in a mixed gas atmosphere with a volume ratio of argon to hydrogen of 14:1 and at a temperature of 950° C., so as to convert the electroplated copper layer into a single-crystal copper layer, after that peeling off the single-crystal copper layer from the substrate to obtain a low-transmission-loss single-crystal copper material with a thickness of 18 μm. The electroplating solution was a copper sulfate solution with a concentration of 130 g/L, and a sulfuric acid solution with a concentration of 70 g/L and the current density was 3 A/dm².

### Example 3

This example provided a low-transmission-loss single-crystal copper material, wherein the difference between Example 3 and Example 1 was that the volume ratio of argon to hydrogen was 10:1.

### Example 4

This example provided a low-transmission-loss single-crystal copper material, wherein the difference between Example 4 and Example 1 was that the volume ratio of argon to hydrogen was 12:1.

### Example 5

This example provided a low-transmission-loss single-crystal copper material, wherein the difference between Example 5 and Example 1 was that the volume ratio of argon to hydrogen was 13:1.

### Example 6

This example provided a low-transmission-loss single-crystal copper material, wherein the difference between Example 6 and Example 1 was that the volume ratio of argon to hydrogen was 15:1.

### Example 7

This example provided a low-transmission-loss single-crystal copper material, wherein the difference between Example 7 and Example 1 was that the volume ratio of argon to hydrogen was 16:1.

### Example 8

This example provided a low-transmission-loss single-crystal copper material, wherein the difference between Example 8 and Example 1 was that the volume ratio of argon to hydrogen was 20:1.

### Example 9

This example provided a low-transmission-loss single-crystal copper material, wherein the difference between Example 9 and Example 1 was that the temperature was 800° C.

### Example 10

This example provided a low-transmission-loss single-crystal copper material, wherein the difference between Example 10 and Example 1 was that the temperature was 850° C.

### Example 11

This example provided a low-transmission-loss single-crystal copper material, wherein the difference between Example 11 and Example 1 was that the temperature was 900° C.

### Example 12

This example provided a low-transmission-loss single-crystal copper material, wherein the difference between Example 12 and Example 1 was that the temperature was 1000° C.

### Example 13

This example provided a low-transmission-loss single-crystal copper material, wherein the difference between Example 13 and Example 1 was that the temperature was 1065° C.

### Example 14

This example provided a low-transmission-loss single-crystal copper material, wherein the difference between Example 14 and Example 2 was that the volume ratio of argon to hydrogen was 10:1.

### Example 15

This example provided a low-transmission-loss single-crystal copper material, wherein the difference between Example 15 and Example 2 was that the volume ratio of argon to hydrogen was 12:1.

### Example 16

This example provided a low-transmission-loss single-crystal copper material, wherein the difference between Example 16 and Example 2 was that the volume ratio of argon to hydrogen was 13:1.

### Example 17

This example provided a low-transmission-loss single-crystal copper material, wherein the difference between Example 17 and Example 2 was that the volume ratio of argon to hydrogen was 15:1.

### Example 18

This example provided a low-transmission-loss single-crystal copper material, wherein the difference between Example 18 and Example 2 was that the volume ratio of argon to hydrogen was 16:1.

### Example 19

This example provided a low-transmission-loss single-crystal copper material, wherein the difference between Example 19 and Example 2 was that the volume ratio of argon to hydrogen was 20:1.

### Example 20

This example provided a low-transmission-loss single-crystal copper material, wherein the difference between Example 20 and Example 2 was that the temperature was 800° C.

### Example 21

This example provided a low-transmission-loss single-crystal copper material, wherein the difference between Example 21 and Example 2 was that the temperature was 850° C.

### Example 22

This example provided a low-transmission-loss single-crystal copper material, wherein the difference between Example 22 and Example 2 was that the temperature was 900° C.

### Example 23

This example provided a low-transmission-loss single-crystal copper material, wherein the difference between Example 23 and Example 2 was that the temperature was 1000° C.

### Example 24

This example provided a low-transmission-loss single-crystal copper material, wherein the difference between Example 24 and Example 2 was that the temperature was 1065° C.

### Example 25

This example provided a low-transmission-loss single-crystal copper material, wherein the difference between Example 25 and Example 1 was that the substrate was a sapphire substrate with a polycrystalline graphene layer on the surface.

### Example 26

This example provided a low-transmission-loss single-crystal copper material, wherein the difference between Example 26 and Example 2 was that the substrate was a single-crystal cooper substrate with a polycrystalline graphene layer on the surface.

### Example 27

This example provided a low-transmission-loss single-crystal copper material, wherein the difference between Example 27 and Example 2 was that the substrate was a polycrystalline copper substrate with a polycrystalline graphene layer on the surface.

### Comparative Example 1

This comparative example provided a copper material. The difference between Comparative Example 1 and Example 1 was that the volume ratio of argon to hydrogen was 5:1.

### Comparative Example 2

This comparative example provided a copper material. The difference between Comparative Example 2 and Example 1 was that the volume ratio of argon to hydrogen was 30:1.

### Comparative Example 3

This comparative example provided a copper material. The difference between Comparative Example 3 and Example 1 was that the temperature was 700° C.

### Comparative Example 4

This comparative example provided a copper material. The difference between Comparative Example 4 and Example 1 was that the temperature was 1100° C.

### Comparative Example 5

This comparative example provided a copper material. The difference between Comparative Example 5 and Example 2 was that the volume ratio of argon to hydrogen was 5:1.

### Comparative Example 6

This comparative example provided a copper material. The difference between Comparative Example 6 and Example 2 was that the volume ratio of argon to hydrogen was 30:1.

### Comparative Example 7

This comparative example provided a copper material. The difference between Comparative Example 7 and Example 2 was that the temperature was 700° C.

### Comparative Example 8

This comparative example provided a copper material. The difference between Comparative Example 8 and Example 2 was that the temperature was 1100° C.

### Experimental Example 1

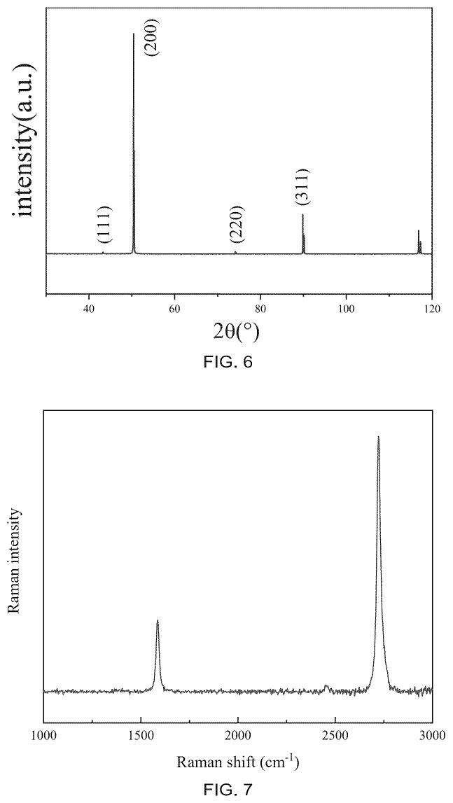

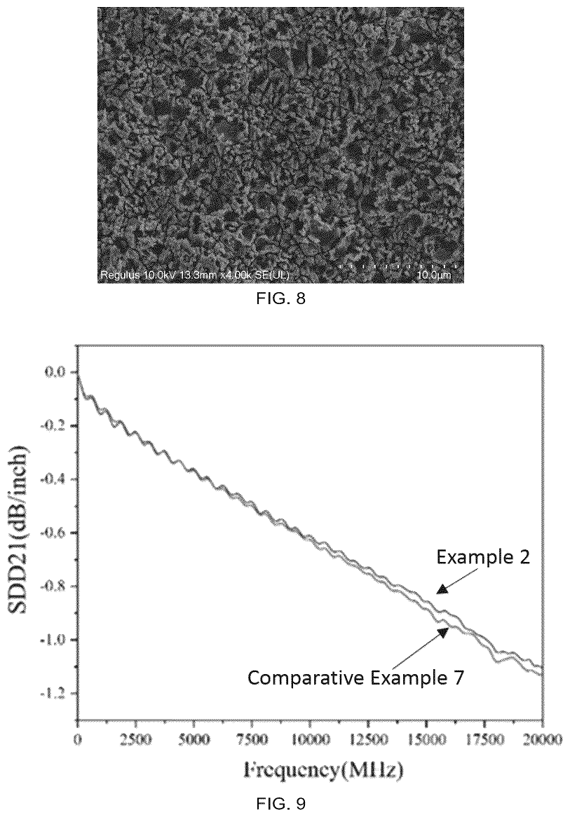

The copper material provided in Example 1 and the copper material provided in Comparative Example 1 were characterized by XRD, and the characterization results are shown in FIG. 5 and FIG. 6. Raman spectrum characterization and SEM characterization were performed on the copper material provided in Example 1, and the characterization results are shown in FIG. 7 and FIG. 8, respectively.

The comparison of FIG. 5 and FIG. 6 shows that the copper material provided in Example 1 has a main crystal phase of (111), which is of single-crystal copper structure, while the copper material provided in Comparative Example 1 has main crystal phases of (200) and (311), which is of polycrystalline copper structure, indicating that the temperature and the volume ratio of argon to hydrogen have a significant influence on the single-crystal property of copper material.

From FIG. 7 and FIG. 8, it can be seen that the copper material provided by Example 1 has higher single-crystal property and lower surface roughness.

### Experimental Example 2

The crystal orientation and surface roughness Rz of the copper materials provided in Examples 1-27 and Comparative Examples 1-8 were characterized, and the characterization results are shown in Table 1.

TABLE 1

| | The volume ratio | | | | Surface |
|---|---|---|---|---|---|
| | of argon to | Temperature | | | roughness Rz |
| | hydrogen | (° C.) | Substrate | Main crystal phase | (μm) |
| Example 1 | 14:1 | 950 | Single-crystal graphene layer - | (111) | 0.82 |
| | | | sapphire | | |
| Example 2 | 14:1 | 950 | Single-crystal graphene layer - | (111) | 1.1 |
| | | | single-crystal copper | | |
| Example 3 | 10:1 | 950 | Single-crystal graphene layer - | (200), (220), (311) | 0.87 |
| | | | sapphire | | |
| Example 4 | 12:1 | 950 | Single-crystal graphene layer - | (111), (200), (220) | 0.85 |
| | | | sapphire | | |
| Example 5 | 13:1 | 950 | Single-crystal graphene layer - | (111), (311), (220) | 0.83 |
| | | | sapphire | | |
| Example 6 | 15:1 | 950 | Single-crystal graphene layer - | (111), (200), (220), | 0.827 |
| | | | sapphire | (311) | |
| Example 7 | 16:1 | 950 | Single-crystal graphene layer - | (111), (200), (220) | 0.84 |
| | | | sapphire | | |
| Example 8 | 20:1 | 950 | Single-crystal graphene layer - | (111), (200), (311) | 0.85 |
| | | | sapphire | | |
| Example 9 | 14:1 | 800 | Single-crystal graphene layer - | (111), (200), (220), | 0.86 |
| | | | sapphire | (311) | |
| Example 10 | 14:1 | 850 | Single-crystal graphene layer - | (111), (200), (311) | 0.87 |
| | | | sapphire | | |
| Example 11 | 14:1 | 900 | Single-crystal graphene layer - | (111), (311), (220) | 0.83 |
| | | | sapphire | | |
| Example 12 | 14:1 | 1000 | Single-crystal graphene layer - | (111), (311), (220) | 0.828 |
| | | | sapphire | | |
| Example 13 | 14:1 | 1065 | Single-crystal graphene layer - | (111), (200), (220) | 0.855 |
| | | | sapphire | | |
| Example 14 | 10:1 | 950 | Single-crystal graphene layer - | (111), (200) | 1.5 |
| | | | single-crystal copper | | |
| Example 15 | 12:1 | 950 | Single-crystal graphene layer - | (111), (200), (220) | 1.4 |
| | | | single-crystal copper | | |
| Example 16 | 13:1 | 950 | Single-crystal graphene layer - | (111), (200), (220), | 1.32 |
| | | | single-crystal copper | (311) | |
| Example 17 | 15:1 | 950 | Single-crystal graphene layer - | (111), (200), (220) | 1.3 |
| | | | single-crystal copper | | |
| Example 18 | 16:1 | 950 | Single-crystal graphene layer - | (111), (200) | 1.5 |
| | | | single-crystal copper | | |
| Example 19 | 20:1 | 950 | Single-crystal graphene layer - | (111), (200), (220) | 1.8 |
| | | | single-crystal copper | | |
| Example 20 | 14:1 | 800 | Single-crystal graphene layer - | (111), (311), (220) | 1.6 |
| | | | single-crystal copper | | |
| Example 21 | 14:1 | 850 | Single-crystal graphene layer - | (111), (200), (220) | 1.9 |
| | | | single-crystal copper | (311) | |
| Example 22 | 14:1 | 900 | Single-crystal graphene layer - | (111), (200), (220) | 1.5 |
| | | | single-crystal copper | | |
| Example 23 | 14:1 | 1000 | Single-crystal graphene layer - | (111), (200), (311) | 1.7 |
| | | | single-crystal copper | | |
| Example 24 | 14:1 | 1065 | Single-crystal graphene layer - | (111), (200), (220) | 1.6 |
| | | | single-crystal copper | | |
| Example 25 | 14:1 | 950 | Polycrystalline graphene layer - | (111), (200), (220), | 0.824 |
| | | | sapphire | (311) | |
| Example 26 | 14:1 | 950 | Polycrystalline graphene layer - | (111), (200), (220), | 1.25 |
| | | | single-crystal copper | (311) | |
| Example 27 | 14:1 | 950 | Polycrystalline graphene layer - | (111), (311), (220) | 1.3 |
| | | | polycrystalline copper | | |
| Comparative | 5:1 | 950 | Single-crystal graphene layer - | (111), (200), (220), | 0.89 |
| Example 1 | | | sapphire | (311) | |
| Comparative | 30:1 | 950 | Single-crystal graphene layer - | (111), (200), (311) | 0.91 |
| Example 2 | | | sapphire | | |
| Comparative | 14:1 | 700 | Single-crystal graphene layer - | (111), (200), (220) | 0.895 |
| Example 3 | | | sapphire | | |
| Comparative | 14:1 | 1100 | Single-crystal graphene layer - | (111), (200), (220) | 0.9 |
| Example 4 | | | sapphire | | |
| Comparative | 5:1 | 950 | Single-crystal graphene layer - | (111), (311), (220) | 1.95 |
| Example 5 | | | single-crystal copper | | |
| Comparative | 30:1 | 950 | Single-crystal graphene layer - | (111), (200), (220) | 1.97 |
| Example 6 | | | single-crystal copper | | |
| Comparative | 14:1 | 700 | Single-crystal graphene layer - | (111), (200), (220) | 1.9 |
| Example 7 | | | single-crystal copper | | |
| Comparative | 14:1 | 1100 | Single-crystal graphene layer - | (111), (200), (311) | 1.92 |
| Example 8 | | | single-crystal copper | | |

From Table 1, it can be seen that the surface roughness Rz of single-crystal copper layer formed by atomic deposition in Example 1, Example 3-13, and Example 25 is lower than that of copper layer formed by atomic deposition in Comparative Example 1-4. The surface roughness Rz of the single-crystal copper layer formed by adopting the annealing of the electroplated copper layer in Example 2, the Example 14-24 and the Example 26-27 is lower than that of the copper layer formed by annealing the electroplated copper layer in Comparative Example 5-8, which shows that the single-crystal copper layer can be effectively formed and the surface roughness Rz of the single-crystal copper layer can be reduced under the conditions of the temperature of 800-1065° C. and the volume ratio of argon to hydrogen as (10-20):1.

Further, the comparison between Examples 3-13 and Example 1 shows that when the temperature is 950° C. and the volume ratio of argon to hydrogen is 14:1, the surface roughness Rz of the single-crystal copper layer is the lowest. Through the comparison of Examples 14-24 and Example 2, it can be seen that when the temperature is 950° C. and the volume ratio of argon to hydrogen is 14:1, the surface roughness Rz of the single-crystal copper layer is the lowest.

Further, the comparison of Example 25, Example 1 and Comparative Examples 1-4 shows that when the copper layer is formed by atomic deposition, the surface roughness Rz of the single-crystal copper layer can be further reduced to the lowest by adopting the sapphire substrate with single-crystal graphene layer rather than the sapphire substrate with polycrystalline graphene layer. Moreover, the influence of the substrate on the surface roughness Rz of the copper layer is not as great as that of the temperature and the volume ratio of argon and hydrogen on the surface roughness Rz of the copper layer

The comparison of Examples 26-27, Example 2 and Comparative Examples 5-8 shows that when the copper layer is formed by annealing the electroplated copper layer, the surface roughness Rz of copper layers made by using the single-crystal graphene layer—single-crystal copper substrate, polycrystalline graphene layer—single-crystal copper substrate and polycrystalline graphene layer—polycrystalline copper substrate increases sequentially. The influence of the substrate on the surface roughness Rz of the copper layer is not as good as that of temperature and the volume ratio of argon and hydrogenhas.

### Experimental Example 3

The copper material provided in Example 2 and the copper material provided in Comparative Example 7 were used as signal layers to prepare PCB, and a vector network analyzer was used to test the transmission loss of the respectively prepared PCBs. The test results are shown in FIG. 9. The preparation steps of the PCB were as follows:
stacking the signal layer, the second dielectric layer and the reference layer are stacked in sequence and laminating them together, then etching the signal transmission line structure on the signal layer to form a primary composite layer; subsequently, coating both sides of the copper-clad plate in the thickness direction with the first dielectric layer, then, covering the primary composite layer respectively on the side of the first dielectric layer away from the copper-clad plate, and contacting the signal layer with the first dielectric layer, and then pressing to form a PCB. The material of the reference layer was ordinary copper foil, the thickness of the reference layer was 18 μm, the thickness of the signal layer was 18 μm, the material of the first dielectric layer and the second dielectric layer was composite materials of glass fiber and resin, the thickness of the first dielectric layer was 75 μm, and the thickness of the second dielectric layer was 356 μm.

As shown in FIG. 9, the transmission loss of the PCB prepared by the copper material provided in Example 2 is significantly lower than that in Comparative Example 7, indicating that the temperature and the volume ratio of argon to hydrogen have a significant effect on the single-crystal property of the copper material, thereby affecting the signal transmission loss of the prepared PCB.

### Experimental Example 4

The copper material provided in Example 2 and the copper material provided in Comparative Example 7 were used as signal layers to prepare PCB, and a vector network analyzer was used to test the transmission loss of the respectively prepared PCBs. The test results are shown in Table 2.

The preparation steps of the PCB were the same as that in Experimental Example 3, and in this experimental example, S-shaped and zigzag signal transmission line structures were respectively configured in the PCBs prepared by the copper materials provided in Example 2 and Comparative Example 7. The difference between the S-shape and the zigzag shape acted only on the shape of the signal transmission line structure, while the dimensions and specifications were exactly the same.

TABLE 2

| | Example 2 | | | Comparative Example 7 | | |
|---|---|---|---|---|---|---|
| | S-shape | Zigzag shape | | | Zigzag shape | |
| | (round | Folded | Folded | | Folded | Folded |
| | corner | angle: | angle: | | angle: | angle: |
| | transition) | 45° | 120° | S-shape | 45° | 120° |
| Transmission | 1.1 | 2 | 1.6 | 1.15 | 2.2 | 1.7 |
| loss | | | | | | |
| (dB/inch) | | | | | | |

It can be seen from Table 2 that the wiring method of the S-shaped round corner transition is better than that of the obtuse angle, and the wiring method of the obtuse angle is better than that of the acute angle. The transmission loss can be effectively reduced, when the etching for the circuit is guaranteed.

### Experimental Example 5

The copper material provided in Example 2 and the copper material provided in Comparative Example 7 were used as signal layers to prepare PCBs, and a vector network analyzer was used to test the transmission loss of the respectively prepared PCBs. The test results are shown in Table 3.

The preparation steps of the PCB were the same as that in Experimental Example 3, and in this experimental example, a methacryloxysilane layer with a thickness of 230 nm was provided between the first dielectric layer and the signal layer in the PCBs prepared by the copper materials provided in Example 2 and Comparative Example 7, respectively.

TABLE 3

| | Example 2 | | Comparative Example 7 | |
|---|---|---|---|---|
| | No | | No | |
| | methacryloxysilane | Methacryloxysilane | methacryloxysilane | Methacryloxysilane |
| | layer provided | layer provided | layer provided | layer provided |
| Bonding | 0.16 | 0.25 | 0.21 | 0.28 |
| force | | | | |
| (KN/m) | | | | |

From Table 3, it can be seen that the addition of silane coupling agent (i.e. methacryloxysilane layer) can enhance the peel strength between the signal layer and the first dielectric layer, thereby ensuring the stability of the PCB structure under the condition of lower roughness.

In summary, the preparation method of the low-transmission-loss single-crystal copper material provided by the present disclosure can significantly reduce the surface roughness Rz of the formed copper material, which is beneficial to further reducing the transmission loss of the entire low-transmission-loss single-crystal copper material. Moreover, the preparation method is simple and easy to operate.

The above descriptions are only preferred embodiments of the present disclosure, and are not intended to limit the present disclosure. For those skilled in the art, various modifications and changes in the present disclosure can be made. Any modifications, equivalent replacements, improvements, etc. made within the spirit and principles of the present disclosure shall be included within the protection scope of the present disclosure.

### INDUSTRIAL APPLICABILITY

The present disclosure relates to the technical field of copper material preparation, in particular to a low-transmission-loss single-crystal copper material and a preparation method thereof, a PCB and a preparation method thereof and an electronic component. The preparation method of the low-transmission-loss single-crystal copper material includes: forming a single-crystal copper layer on a substrate whose surface is a graphene layer, in a mixed gas atmosphere of argon and hydrogen and at a temperature of 800-1065° C.; and peeling off the single-crystal copper layer from the substrate. The volume ratio of argon to hydrogen in the mixed gas is (10-20):1. The preparation method of the low-transmission-loss single-crystal copper material provided by the present disclosure can significantly reduce the surface roughness Rz of the formed copper material, which is beneficial to further reducing the transmission loss of the entire low-transmission-loss single-crystal copper material, and the preparation method is simple and easy to operate.

In addition, it can be understood that the low-transmission-loss single-crystal copper material and its preparation method, a PCB and its preparation method and the electronic component provided by the present disclosure are reproducible and can be used in various applications. For example, the low-transmission-loss single-crystal copper material and its preparation method, the PCB and its preparation method and the electronic component of the present disclosure can be used in the technical field of copper material preparation.

What is claimed is:

1. A preparation method for a low-transmission-loss single-crystal copper material, wherein the preparation method comprises: forming a single-crystal copper layer on a substrate with a surface of a graphene layer, in an atmosphere of a mixed gas of argon and hydrogen and at a temperature of 800-1065° C., and then peeling off the single-crystal copper layer from the substrate, wherein
a volume ratio of argon to hydrogen in the mixed gas is (10-20):1.

2. The preparation method according to claim 1, wherein the graphene layer is a single-crystal graphene layer.

3. The preparation method according to claim 1, wherein a preparation step of the single crystal copper layer comprises: forming the single-crystal copper layer on the graphene layer of the substrate by atomic deposition, in the atmosphere of the mixed gas and at the temperature of 800-1065° C.

4. The preparation method according to claim 3, wherein a temperature of preparing the single-crystal copper layer is 900-1000° C. and the volume ratio of argon and hydrogen in the mixed gas is (13-15):1; and
optionally, the substrate is a sapphire substrate whose surface is the graphene layer.

5. The preparation method according to claim 1, wherein a preparation step of the single-crystal copper layer comprises electroplating copper on the graphene layer of the substrate to form an electroplated copper layer, then annealing in the atmosphere of the mixed gas and at the temperature of 800-1065° C. to transform the electroplated copper layer to the single-crystal copper layer.

6. The preparation method according to claim 5, wherein a temperature for preparing the single-crystal copper layer is 900-1000° C., and the volume ratio of argon to hydrogen in the mixed gas is (13-15):1;
optionally, the substrate is a copper substrate with the graphene layer on a surface; and
optionally, the substrate is a single-crystal copper substrate with the graphene layer on a surface.

7. A low-transmission-loss single-crystal copper material, wherein
the low-transmission-loss single-crystal copper material is made by the preparation method of a low-transmission-loss single-crystal copper material according to claim 1.

8. A PCB, wherein the PCB comprises a signal layer and a first dielectric layer covering a surface of the signal layer, wherein
a material of the signal layer comprises the low-transmission-loss single-crystal copper according to claim 7;
optionally, the signal layer has a signal transmission line structure, wherein the signal transmission line structure has a plurality of sequentially connected S-shaped transmission units;
optionally, the PCB further comprises a base and a first composite layer and a second composite layer respectively covering two opposite sides of the base in a thickness direction; and the first composite layer and the second composite layer each comprise the first dielectric layer, the signal layer, a second dielectric layer and a reference layer that sequentially cover a surface of the base along the thickness direction of the base;
optionally, along an extending direction of the signal transmission line structure, a distance between two opposite ends of the signal transmission line structure in the first composite layer and a distance between two opposite ends of the signal transmission line structure in the second composite layer are different;
optionally, along a direction from the first dielectric layer to the second dielectric layer, a width of the signal transmission line structure gradually increases, and a difference between a surface width of the signal transmission line structure close to the first dielectric layer and a surface width of the signal transmission line structure close to the second dielectric layer is less than 0.3 mil; and
optionally, the PCB further comprises a connection layer, wherein the connection layer is disposed between the first dielectric layer and the signal layer, and a material of the connection layer is a silane coupling agent.

9. The PCB according to claim 8, wherein a thickness of the reference layer is 10 μm-100 μm, a thickness of the signal layer is 3 μm-70 μm, materials of the first dielectric layer and the second dielectric layer both are a composite material of glass fiber and resin, and thicknesses of the first dielectric layer and the second dielectric layer are each 10 μm-400 μm independently.

10. The PCB according to claim 8, wherein the distance between the two opposite endpoints of the signal transmission line structure in the first composite layer is 7 inch-10 inch, and the distance between the two opposite endpoints of the signal transmission line structure in the second composite layer is 12 inch-15 inch.

11. The PCB according to claim 8, wherein along the direction from the first dielectric layer to the second dielectric layer, the width of the signal transmission line structure gradually increases, and the difference between the surface width of the signal transmission line structure close to the first dielectric layer and the surface width of the signal transmission line structure close to the second dielectric layer is 0.1 mil-0.3 mil.

12. The PCB according to claim 8, wherein the surface width of the signal transmission line structure close to the first dielectric layer is 7.2 mil-7.3 mil, and the surface width of the signal transmission line structure close to the second dielectric layer is 7.4 mil-7.6 mil.

13. The PCB according to claim 8, wherein the silane coupling agent comprises at least one of methacryloxysilane and 3-aminopropyltrimethoxysilane.

14. (canceled)

15. (canceled)

16. The preparation method according to claim 2, wherein a preparation step of the single crystal copper layer comprises: forming the single-crystal copper layer on the graphene layer of the substrate by atomic deposition, in the atmosphere of the mixed gas and at the temperature of 800-1065° C.

17. The preparation method according to claim 2, wherein a preparation step of the single-crystal copper layer comprises electroplating copper on the graphene layer of the substrate to form an electroplated copper layer, then annealing in the atmosphere of the mixed gas and at the temperature of 800-1065° C. to transform the electroplated copper layer to the single-crystal copper layer.

18. The PCB according to claim 9, wherein the distance between the two opposite endpoints of the signal transmission line structure in the first composite layer is 7 inch-10 inch, and the distance between the two opposite endpoints of the signal transmission line structure in the second composite layer is 12 inch-15 inch.

19. The PCB according to claim 9, wherein along the direction from the first dielectric layer to the second dielectric layer, the width of the signal transmission line structure gradually increases, and the difference between the surface width of the signal transmission line structure close to the first dielectric layer and the surface width of the signal transmission line structure close to the second dielectric layer is 0.1 mil-0.3 mil.

20. The PCB according to claim 10, wherein along the direction from the first dielectric layer to the second dielectric layer, the width of the signal transmission line structure gradually increases, and the difference between the surface width of the signal transmission line structure close to the first dielectric layer and the surface width of the signal transmission line structure close to the second dielectric layer is 0.1 mil-0.3 mil.

21. The PCB according to claim 9, wherein the surface width of the signal transmission line structure close to the first dielectric layer is 7.2 mil-7.3 mil, and the surface width of the signal transmission line structure close to the second dielectric layer is 7.4 mil-7.6 mil.

22. The PCB according to claim 9, wherein the silane coupling agent comprises at least one of methacryloxysilane and 3-aminopropyltrimethoxysilane.
